(19) United States
(12) Patent Application Publication
(10) Pub. No.: US 2010/0123201 A1
(43) Pub. Date: May 20, 2010

(54) Semiconductor Devices

(76) Inventors: Sang-Hun Jeon, Yongin-si (KR); Moon-Sook Lee, Seoul (KR)

Correspondence Address: MYERS BIGEL SIBLEY & SAJOVEC, PO BOX 37428, RALEIGH, NC, 27627, US

(21) Appl. No.: 12/614,697

(22) Filed: Nov. 9, 2009

(30) Foreign Application Priority Data
Nov. 14, 2008 (KR) 10-2008-0113384

(51) Int. Cl. H01L 27/088

(52) U.S. Cl. 257/392; 257/E27.06

(57) ABSTRACT

A semiconductor device includes a substrate, a first channel layer pattern, a second channel layer pattern, a first transistor and a second transistor. The substrate has a first region and a second region. The first channel layer pattern is formed in the first region of the substrate and has a first volume. The second channel layer pattern is formed in the second region of the substrate and has a second volume that is different from the first volume. The first transistor includes a first gate insulation layer pattern on the first channel layer pattern, a first gate electrode on the first gate insulation layer pattern, and a first source/drain region in contact with the first channel layer pattern. The second transistor includes a second gate insulation layer pattern on the second channel layer pattern, a second gate electrode on the second gate insulation layer pattern, and a second source/drain region in contact with the second channel layer pattern.

### CROSS REFERENCE TO RELATED APPLICATION AND CLAIM OF PRIORITY

This application claims priority under 35 USC §119 to Korean Patent Application No. 10-2008-0113384, filed on Nov. 14, 2008 in the Korean Intellectual Property Office (KIPO), the disclosure of which is herein incorporated by reference in its entirety.

### BACKGROUND

Example embodiments relate to semiconductor devices and methods of manufacturing the same. More particularly, example embodiments relate to semiconductor devices including transistors having different characteristics and methods of manufacturing the same.

Chips used in radio frequency identifications (RFIDs), electronic article surveillance (EAS) tags, EAS sensors, etc. are generally manufactured by a printing process because of low costs.

Channel layers formed by a printing process may include an organic semiconductor layer. However, organic semiconductor materials may have low charge mobility, so that it may be difficult to manufacture a high quality transistor using organic semiconductor material. Thus, transistors having channel layers including semiconductor oxide have been developed, because semiconductor oxide may have high charge mobility.

A channel layer made from semiconductor oxide generally has one conductivity type because a semiconductor oxide layer having more than one conductivity type may be unstable. Additionally, forming a channel layer including two conductivity types using semiconductor oxide may involve the use of expensive manufacturing apparatus and/or complicated processes. Thus, manufacturing a transistor having a channel region and a source/drain region using semiconductor oxide, which have different conductivity types from each other, may be difficult and/or expensive.

A source/drain region in a transistor having a semiconductor oxide channel layer may be formed using a metal. The transistor may be a majority carrier device in which a channel layer and charge carriers have the same conductivity type. The majority carrier device transistor may be operated primarily in an accumulation mode. A transistor operated in the accumulation mode may be turned on more easily than that a transistor operated in an inverse mode because a potential barrier between a source and a gate may be relatively low, and the threshold voltage distribution thereof may be wider.

A continued need exists for a transistor having a desired threshold voltage level and capable of being manufactured at a low cost.

### SUMMARY

A semiconductor device according to some embodiments includes a substrate, a first channel layer pattern, a second channel layer pattern, a first transistor and a second transistor. The substrate has a first region and a second region. The first channel layer pattern having a first volume is formed in the first region of the substrate. The second channel layer pattern having a second volume is formed in the second region of the substrate. The first transistor includes a first gate insulation layer pattern on the first channel layer pattern, a first gate electrode on the first gate insulation layer and a first source/drain region in contact with the first channel layer pattern. The second transistor includes a second gate insulation layer pattern on the second channel layer pattern, a second gate electrode on the second gate insulation layer, and a second source/drain region in contact with the second channel layer pattern.

In some embodiments, the first and second channel layer patterns may include a semiconductor oxide.

In some embodiments, the second volume may be larger than the first volume, so that the first transistor may have a threshold voltage higher than that of the second transistor.

In some embodiments, the first transistor may have a positive threshold voltage, and the second transistor may have a negative threshold voltage.

In some embodiments, at least one of the first and second channel layer patterns may have ions implanted to neutralize hydrogen therein.

In some embodiments, the first channel layer has a first thickness such that the first channel layer is fully depleted when zero bias is applied to the first gate electrode. Furthermore, in some embodiments, the second channel layer has a second thickness that is greater than the first thickness and that is selected such that the second channel layer is not fully depleted when zero bias is applied to the second gate electrode.

In some embodiments, the substrate may include an insulator.

The first channel layer and the second channel layer may be formed of the same material.

Some embodiments provide methods of manufacturing a semiconductor device. According to some embodiments, a first channel layer pattern is formed in a first region of a substrate to have a first volume. A second channel layer pattern is formed in a second region of the substrate to have a second volume. A first transistor including a first gate insulation layer pattern, a first gate electrode and a first source/drain region is formed on the first channel layer pattern. A second transistor including a second gate insulation layer pattern, a second gate electrode and a second source/drain region is formed on the second channel layer pattern.

In some embodiments, the first and second channel layer patterns may be formed by a printing process.

In some embodiments, the first and second volumes may be controlled so that the first and second transistors may have desired threshold voltages.

In some embodiments, the first volume may be controlled to be smaller than the second volume, so that the first transistor may have a threshold voltage higher than that of the second transistor.

In some embodiments, ions for neutralizing hydrogen in at least one of the first and second channel layer patterns may be implanted into the at least one of the first and second channel layer patterns.

According to some embodiments, transistors having various threshold voltages may be easily manufactured by controlling the thickness of channel layer patterns. Thus, a semiconductor device including transistors according to some embodiments may have good electrical characteristics.

### BRIEF DESCRIPTION OF THE DRAWINGS

Example embodiments will be more clearly understood from the following detailed description taken in conjunction with the accompanying drawings.

FIG. 1 is a cross-sectional view illustrating transistors in accordance with some embodiments;

FIG. 2A is a band diagram illustrating a first transistor on a first channel layer pattern having a relatively small volume, and FIG. 2B is a band diagram illustrating a second transistor on a second channel layer pattern having a relatively large volume;

FIGS. 3 to 7 are cross-sectional views illustrating methods of manufacturing the transistors shown in FIG. 1;

FIGS. 8 to 9 are cross-sectional views illustrating further methods of manufacturing the transistors shown in FIG. 1;

FIG. 10 is a cross-sectional view illustrating an inverter including the transistors in FIG. 1;

FIG. 11 is an equivalent circuit diagram of the inverter shown in FIG. 10;

FIG. 12 is a cross-sectional view illustrating transistors in accordance with other embodiments;

FIGS. 13 to 16 are cross-sectional views illustrating methods of manufacturing the transistors shown in FIG. 12; and

FIG. 17 is a cross-sectional view illustrating further methods of manufacturing the transistors shown in FIG. 12.

### DETAILED DESCRIPTION OF EMBODIMENTS

Various embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of this specification and the relevant art and will not be interpreted in an idealized or overly formal sense unless expressly so defined herein.

Hereinafter, example embodiments will be explained in detail with reference to the accompanying drawings.

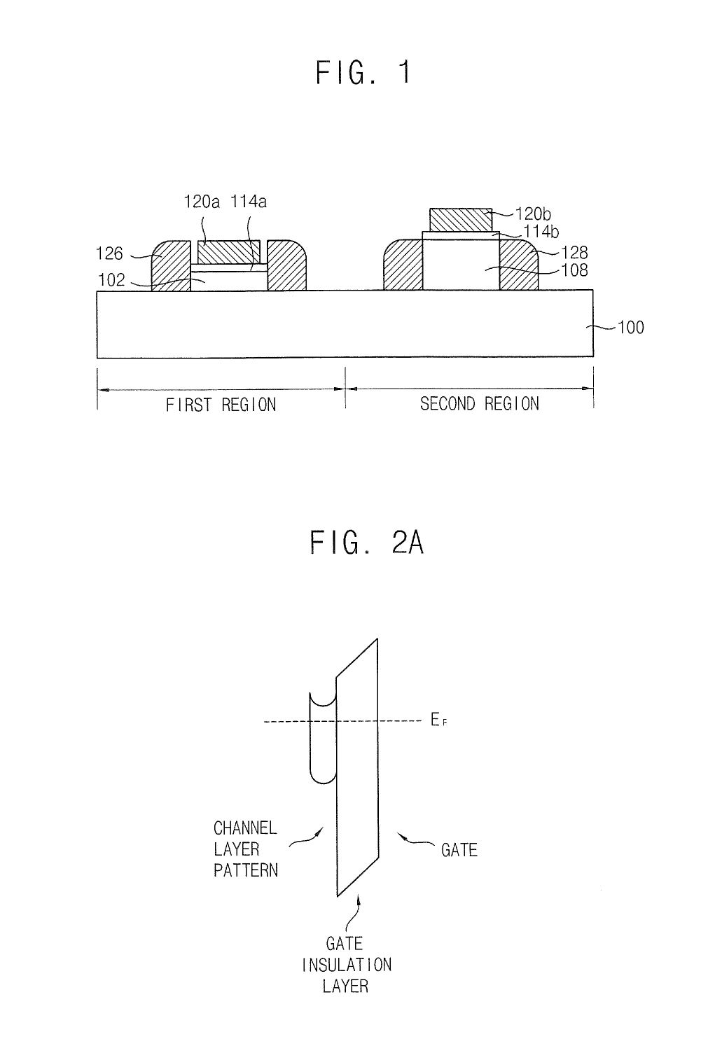

FIG. 1 is a cross-sectional view illustrating transistors in accordance with some embodiments.

Referring to FIG. 1, a substrate 100 having a first region and a second region may be provided. The substrate 100 may include an insulator such as glass, plastic, etc. Alternatively, the substrate 100 may include a semiconductor substrate such as a silicon substrate or a SOI (silicon-on-insulator) substrate, however, in that case the substrate 100 may further include an insulation layer thereon. First transistors having a relatively high threshold voltage may be formed in the first region, and second transistors having a relatively low threshold voltage may be formed in the second region.

A first channel layer pattern 102 having a first volume may be formed in the first region of the substrate 100. A second channel layer pattern 108 having a second volume larger than the first volume may be formed in the second region of the substrate 100. In some embodiments, the length and width of the first and second channel layer patterns 106, 108 may be the same, and the difference in volume of the first and second channel layer patterns 106, 108 may be caused by a difference in thickness of the first and second channel layer patterns 106, 108 (i.e., the height of the first and second channel layer patterns 106, 108 above the substrate 100).

The first and second channel layer patterns 102 and 108 may include a semiconductor oxide. In some embodiments, the first and second channel layer patterns 102 and 108 may include nanowires and/or nano-particles. The first and second channel layer patterns 102 and 108 may include, for example, an oxide such as zinc oxide. However, in other embodiments, the first and second channel layer patterns 102 and 108 may include, for example, gallium nitride, silicon, silicon germanium, cadmium sulfide, vanadium oxide, nickel oxide, carbon, gallium arsenide, silicon carbide, zinc sulfide, zinc selenide, zinc telluride, cadmium sulfide, cadmium selenide, cadmium telluride, mercury selenide, mercury telluride, copper aluminum selenide, aluminum indium phosphorus, aluminum gallium arsenide, aluminum indium arsenide, aluminum gallium stibium, aluminum indium stibium, gallium indium phosphorus, gallium indium stibium, gallium phosphorus arsenide, gallium arsenide stibium, indium phosphorus arsenide, indium arsenide stibium, etc.

The threshold voltages of transistors on the first and second channel layer patterns 102 and 108 may be varied according to the first and second volumes of the first and second channel layer patterns 102 and 108. In particular, a first transistor on the first channel layer pattern 102 having a smaller volume may have a threshold voltage that is higher than that of a second transistor on the second channel layer pattern 108 having a larger volume.

When the first and second channel layer patterns 102 and 108 are thin films, the first channel layer pattern 102 may have a thickness that is thinner than that of the second channel layer pattern 108. When the first and second channel layer patterns 102 and 108 are columns, the first channel layer pattern 102 may have a diameter that is smaller than that of the second channel layer pattern 108. When the first and second channel layer patterns 102 and 108 are regular polyhedrons, the first channel layer pattern 102 may have a side that is smaller than that of the second channel layer pattern 108.

A first gate insulation layer pattern 114a and a first gate electrode 120a may be formed on the first channel layer pattern 102. The first gate insulation layer pattern 114a may include an organic material, an inorganic material, a hybrid material, etc.

A second gate insulation layer pattern 114b and a second gate electrode 120b may be formed on the second channel layer pattern 108. The second gate insulation layer pattern 114b may include an organic material, an inorganic material, a hybrid material, etc.

The first and second gate insulation layer patterns 114a and 114b may include substantially the same material. Furthermore, the first and second gate electrodes 120a and 120b may include substantially the same material.

First metallic patterns 126 may be formed on the substrate 100 to contact sidewalls of the first channel layer pattern 102. The first metallic patterns 126 may be spaced apart from the first gate electrode 120a. The first metallic patterns 126 may serve as first source/drain regions of the first transistor.

Second metallic patterns 128 may be formed on the substrate 100 to contact sidewalls of the second channel layer pattern 108. The second metallic patterns 128 may be spaced apart from the second gate electrode 120b. The second metallic patterns 128 may serve as second source/drain regions of the second transistor. The first and second metallic patterns 126 and 128 may include substantially the same material.

The first and second transistors may have substantially the same structure except for the volumes of the first and second channel layer patterns 102 and 108. The transistors on the same substrate 100 may have threshold voltage characteristics that are related to the volumes of their respective channel layer patterns 102 and 108. Additionally, one type of transistor may be also manufactured on the substrate 100 to have a desired threshold voltage by controlling a volume of a channel layer pattern.

Hereinafter, the relationship between a volume of a channel layer pattern and a threshold voltage of a transistor will be explained. A semiconductor oxide used for the channel layer pattern may have n-type conductivity or p-type conductivity. For example, a transistor on a channel layer pattern made from an n-type semiconductor oxide is explained.

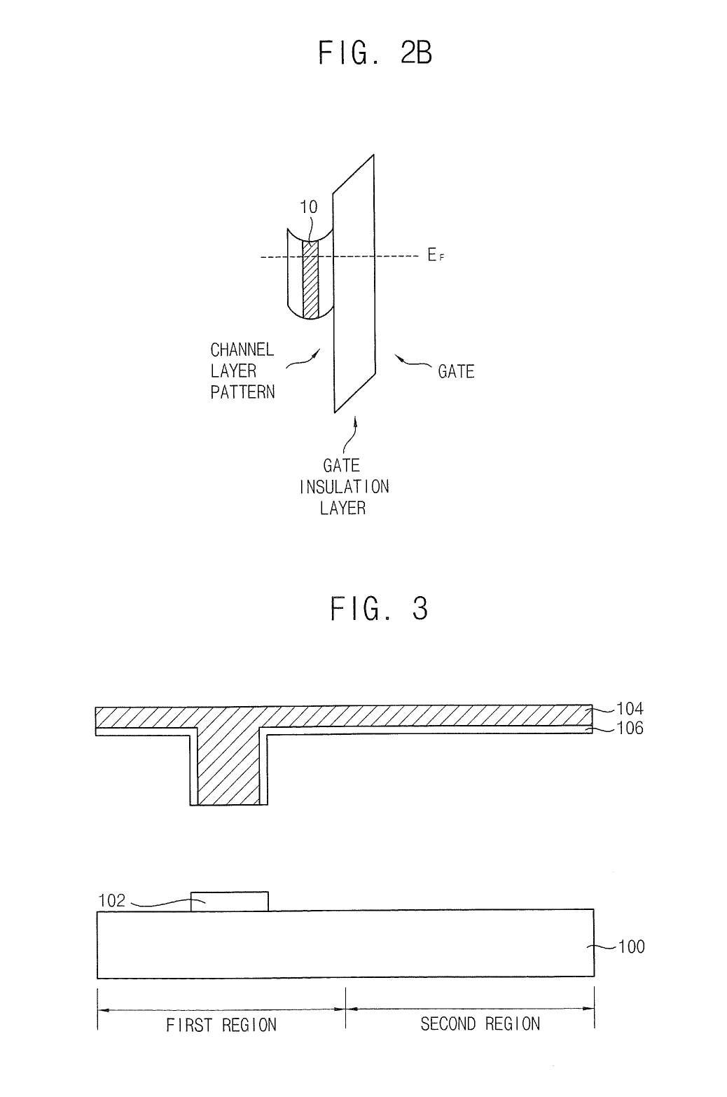

FIG. 2A is a band diagram illustrating a first transistor on a first channel layer pattern having a relatively small volume. FIG. 2B is a band diagram illustrating a second transistor on a second channel layer pattern having a relatively large volume. In FIGS. 2A and 2B, E_{F} indicates the Fermi energies of the transistors.

Referring to FIG. 2A, when the first transistor is operated, a portion of the first channel layer pattern contacting a gate insulation layer may be depleted. The first channel layer pattern has a small volume, and thus the whole first channel layer pattern may be depleted. Accordingly, the threshold voltage of the first transistor may be relatively high.

Referring to FIG. 2B, when the second transistor is operated, a portion of the second channel layer pattern contacting a gate insulation layer may be depleted. The second channel layer pattern has a large volume, and thus only the portion of the second channel layer pattern contacting the gate insulation layer (and not the entire second channel layer pattern) may be depleted. Accordingly, a conductive channel region 10 may be formed in the second channel layer pattern, and the threshold voltage of the second transistor may be relatively low. The threshold voltage may be equal to or less than 0V.

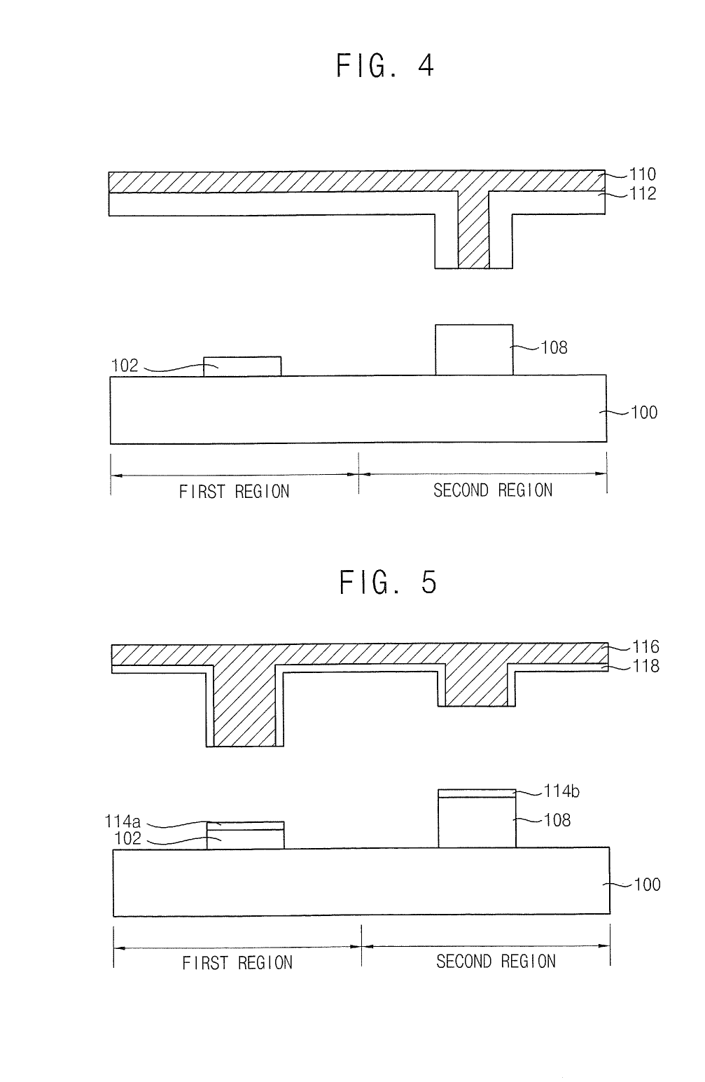

FIGS. 3 to 7 are cross-sectional views illustrating methods of manufacturing the transistors shown in FIG. 1.

Referring to FIG. 3, a substrate 100 having first and second regions may be provided. The first channel layer pattern 102 may be formed in the first region of the substrate 100 by, for example, a printing process. In particular, a first channel material 106 may be coated on a first mold 104. The first mold 104 may have a protrusion corresponding to a first portion of the substrate 100 on which the first channel layer pattern 102 may be formed. The first mold 104 may be pressed onto the substrate 100, and thus the first channel material 106 may be transferred from the protrusion of the first mold 104 to the substrate 100. As a result, the first channel layer pattern 102 may be formed in the first region of the substrate 100. The first channel layer pattern 102 may have a first volume.

Referring to FIG. 4, the second channel layer pattern 108 having a second volume that is larger than the first volume may be formed in the second region of the substrate 100. In particular, a second channel material 118 may be coated on a second mold 110. The second mold 110 may have a protrusion corresponding to a second portion of the substrate 100 on which the second channel layer pattern 108 may be formed. The second mold 110 may be pressed onto the substrate 100, and thus the second channel material 118 may be transferred from the protrusion of the second mold 110 to the substrate 100. As a result, the second channel layer pattern 110 may be formed in the second region of the substrate 100.

Referring to FIG. 5, the first gate insulation layer pattern 114a and the second gate insulation layer pattern 114b may be formed on the first channel layer pattern 102 and the second channel layer pattern 108, respectively. The first and second gate insulation layer patterns 114a and 114b may be formed, for example, by a printing process.

In particular, a gate insulation material 118 may be coated on a third mold 116 having protrusions corresponding to the first and second portions of the substrate 100, respectively. The third mold 116 may be pressed onto the substrate 100, and thus the gate insulation material 118 may be transferred from the third mold 116 to the substrate 100. As a result, the first and second gate insulation layer patterns 114a and 114b may be formed. The first and second gate insulation layer patterns 114a and 114b may include substantially the same material, i.e., the gate insulation material 118. The gate insulation material 118 may include an organic material, an inorganic material, a hybrid material, etc. For example, the first and second gate insulation layer patterns 114a and 114b may include silicon oxide.

Referring to FIG. 6, the first gate electrode 120a and the second gate electrode 120b may be formed on the first and second gate insulation layer patterns 114a and 114b, respectively. The first and second gate electrodes 120a and 120b may be formed, for example, by a printing process.

In particular, a gate electrode material 124 may be coated on a fourth mold 122 having protrusions corresponding to third and fourth portions of the substrate 100, respectively. The third and fourth portions of the substrate 100 may be within the first and second portions thereof, respectively. That is, the third and fourth portions of the substrate 100 may be narrower than the first and second portions of the substrate 100 so that the gate electrodes do not extend all the way to the sides of the first and second gate insulation layer patterns 114a and 114b. The fourth mold 122 may be pressed onto the substrate 100, and thus the gate electrode material 124 may be transferred from the fourth mold 122 to the substrate 100. As a result, the first and second gate electrodes 120a and 120b may be formed. The first and second gate electrodes 120a and 120b may include substantially the same material, i.e., the gate electrode material 124. The gate electrode material 124 may include a metal.

Referring to FIG. 7, first metallic patterns 126 may be formed on the substrate 100 to contact the sidewalls of the first channel layer pattern 102. Additionally, second metallic patterns 128 may be formed on the substrate 100 to contact the sidewalls of the second channel layer pattern 108. The first metallic patterns 126 may be spaced apart from the first gate electrode 120a, and the second metallic patterns 128 may be spaced apart from the second gate electrode 120b. The first metallic patterns 126 may serve as the first source/drain regions of the first transistor, and the second metallic patterns 128 may serve as the second source/drain regions of the second transistor.

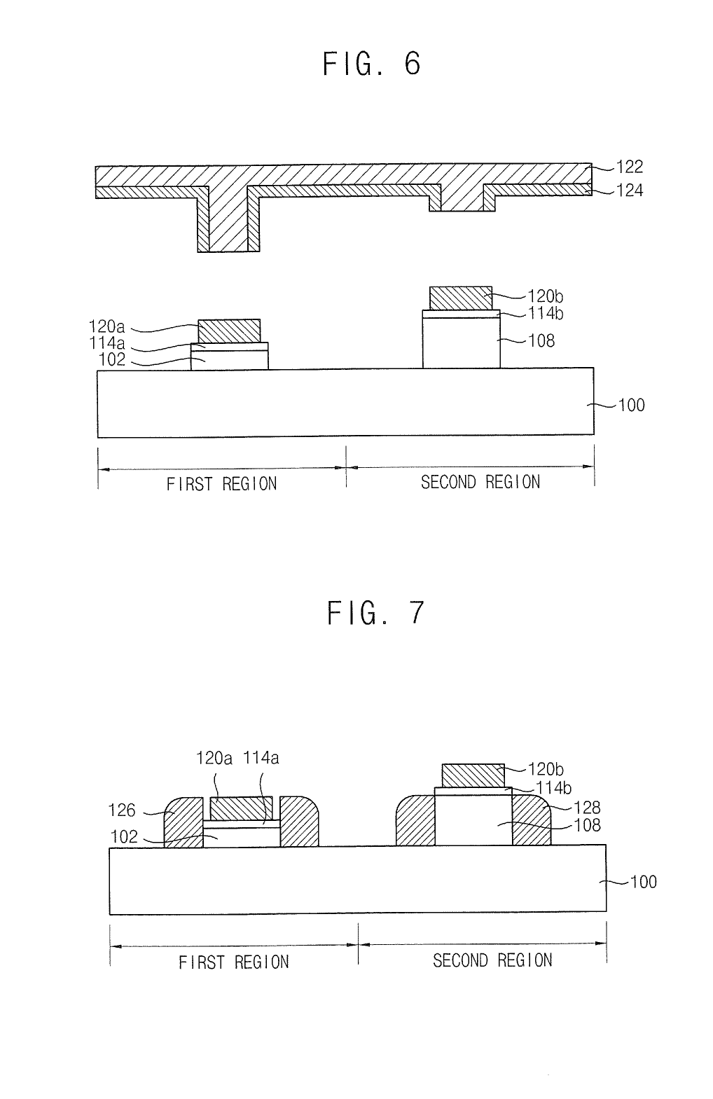

FIGS. 8 to 9 are cross-sectional views illustrating further methods of manufacturing the transistors shown in FIG. 1.

Referring to FIG. 8, the substrate 100 having the first and second regions may be provided. The first channel layer pattern 102 may be formed in the first region of the substrate 100, for example, by a printing process. The first channel layer pattern 102 may be formed using a semiconductor oxide. The first channel layer pattern 102 may include nanowires and/or nano-particles. The first channel layer pattern 102 may include, for example, an oxide such as zinc oxide. In some embodiments, the first channel layer pattern 102 may include a material, such as gallium nitride, silicon, silicon germanium, cadmium sulfide, vanadium oxide, nickel oxide, carbon, gallium arsenide, silicon carbide, zinc sulfide, zinc selenide, zinc telluride, cadmium sulfide, cadmium selenide, cadmium telluride, mercury selenide, mercury telluride, copper aluminum selenide, aluminum indium phosphorus, aluminum gallium arsenide, aluminum indium arsenide, aluminum gallium stibium, aluminum indium stibium, gallium indium phosphorus, gallium indium stibium, gallium phosphorus arsenide, gallium arsenide stibium, indium phosphorus arsenide, indium arsenide stibium, etc. In some embodiments, the first channel layer pattern 102 may be formed using a metal oxide.

Referring to FIG. 9, ions for neutralizing hydrogen in the first channel layer pattern 102 may be implanted into the first channel layer pattern 102, so that the threshold voltage of the first transistor may be increased. In particular, the first channel layer pattern 102 may include hydrogen serving as a donor, and thus the n-type transistor may have a high conductivity and a low threshold voltage. The ions may neutralize hydrogen in the first channel layer pattern 102, thereby increasing the threshold voltage. The transistor may have a threshold voltage of equal to or more than 0V.

The ions may include halogen elements, non-metallic elements having a high electronegativity, etc. such as fluorine, chlorine, bromine, indium, oxygen, sulfur, selenium, tellurium, etc. These may be doped into the first channel layer pattern 102 alone or in a combination thereof. The implantation may be performed by a plasma doping process, a gas vapor deposition process, a melting process, etc.

The implanted ions may be activated, e.g., by a heat treatment process.

Processes substantially the same or similar to those illustrated with reference to FIGS. 4 to 7 may be performed to complete the transistors in FIG. 1. The transistors formed using the methods illustrated with reference to FIGS. 8 and 9 may have an increased threshold voltage relative to transistors that are not provided with ions to neutralize hydrogen in the channel layer pattern 102.

In some embodiments, the implantation process may be performed after forming the first and second channel layer patters 102 and 108. In particular, after forming the first and second channel layer patterns 102 and 108 on the substrate 100, ions for neutralizing hydrogen in the first and second channel layer patterns 102 and 108 may be implanted.

The ion implantation process may be applied to a method of manufacturing any majority carrier device transistors in which a high threshold voltage is needed. Additionally, any n-type transistor having a desired threshold voltage may be manufactured by providing the ions for neutralizing hydrogen.

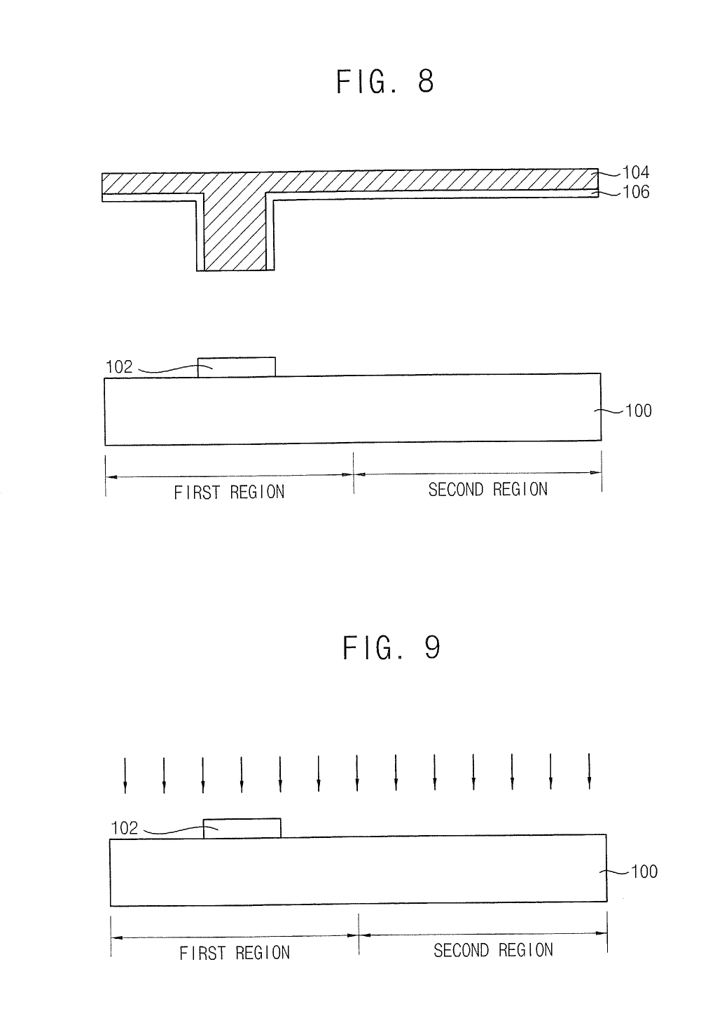

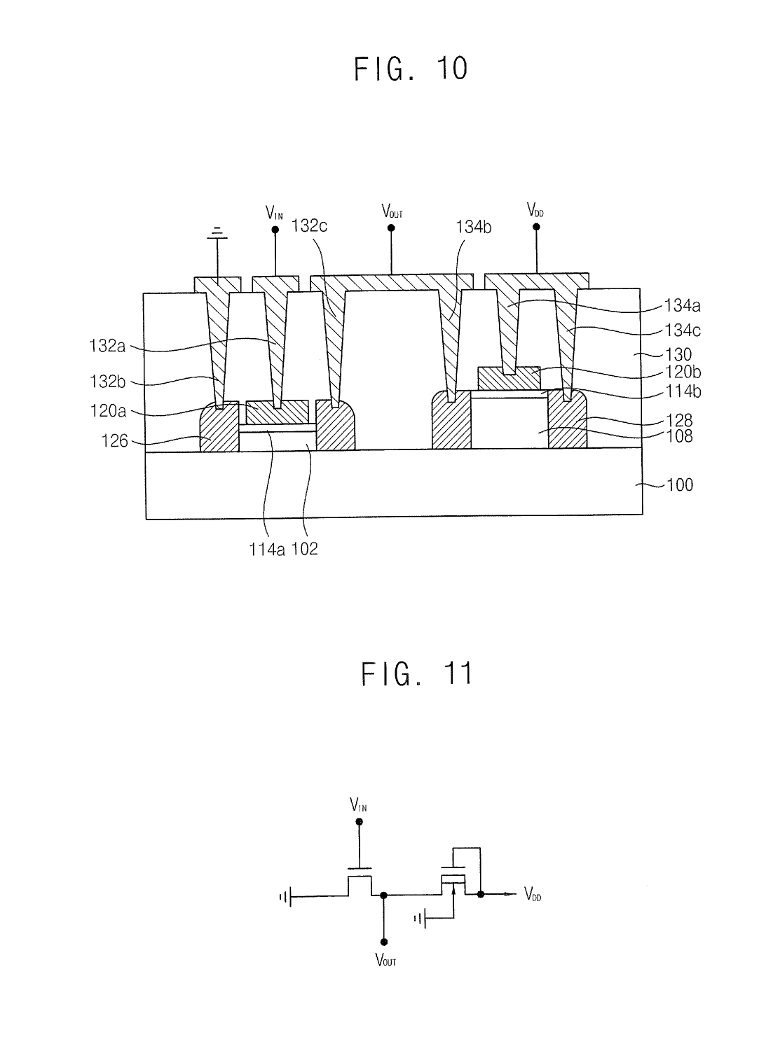

FIG. 10 is a cross-sectional view illustrating an inverter including the transistors in FIG. 1. FIG. 11 is an equivalent circuit diagram of the inverter shown in FIG. 10.

Referring to FIGS. 10 and 11, the inverter may include the first and second transistors on the first and second channel layer patterns 102 and 108, respectively. The first channel layer pattern 102 may have a volume smaller than that of the second channel layer pattern 108.

The first channel layer pattern 102 may have a small volume so that the entire portion of the first channel layer pattern 102 may be depleted when the first transistor is operated at zero bias. Thus, the first transistor may have a high threshold voltage of equal to or more than 0V. The second channel layer pattern 108 may have a large volume, thereby having a low threshold voltage of equal to or less than about 0V.

An insulation layer 130 may be formed on the substrate 100 to cover the first and second transistors. The insulation layer 130 may include silicon oxide.

A plurality of contact plugs may be formed through the insulation layer 130. In particular, a first contact plug 132a connected to the first gate electrode 120a, a second contact plug 132b connected to a source region of the first transistor, and a third contact plug 132c connected to a drain region of the first transistor may be formed. Additionally, a fourth contact plug 134a connected to the second gate electrode 120b, a fifth contact plug 134b connected to a drain region of the second transistor, and a sixth contact plug 134c connected to a source region of the second transistor may be formed.

The fourth and sixth contact plugs 134a and 134c may be electrically connected to each other, so that the same voltage may be applied to the second gate electrode 120b and the source region of the second transistor.

The third and fifth contact plugs 132c and 134b may be electrically connected to each other, so that the drain region of the first transistor may have the same voltage level as that of the second transistor. The drain regions of the first and second transistors may serve as an output terminal of the inverter.

An input voltage may be applied to the first contact plug 132a serving as an input terminal Vᵢₙ, of the inverter. The second contact plug 132b may be grounded.

As shown in FIG. 11, when a high level signal equal to or higher than the threshold voltage is input to the input terminal, the first transistor may be turned on so that a low level signal may be output at the output terminal Vₒᵤₜ. When a low level signal equal to or lower than the threshold voltage is input to the input terminal, the first transistor may be turned off so that a high level signal may be output at the output terminal Vₒᵤₜ.

As described above, transistors on the same conductive type channel layer patterns may serve as different conductivity type transistors by controlling the volumes of the channel layer patterns. Thus, an inverter including the different conductivity type transistors may be manufactured easily.

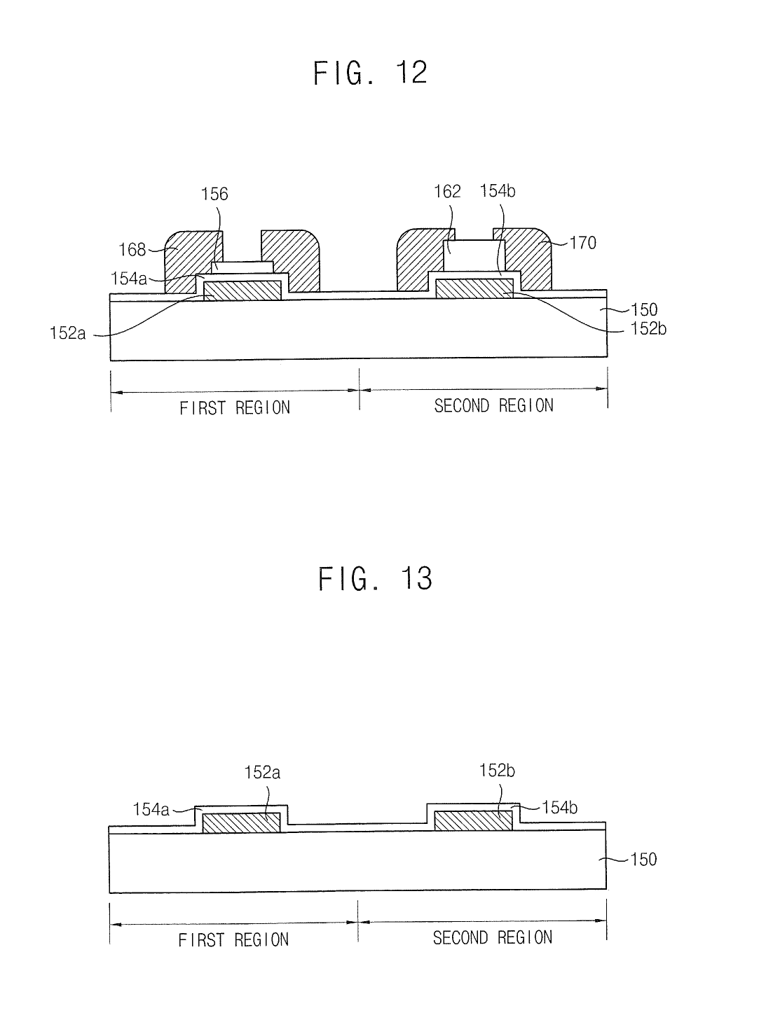

FIG. 12 is a cross-sectional view illustrating transistors in accordance with other example embodiments.

Referring to FIG. 12, a substrate 150 having a first region and a second region may be provided. First transistors having a relatively high threshold voltage may be formed in the first region, and second transistors having a relatively low threshold voltage may be formed in the second region.

A first gate electrode 152a may be formed in the first region of the substrate 150, and a second gate electrode 152b may be formed in the second region of the substrate 150.

A first gate insulation layer 154a may be formed on the first gate electrode 152a, and a second gate insulation layer 154b may be formed on the second gate electrode 152b.

A first channel layer pattern 156 having a first volume may be formed on the first gate insulation layer 154a. The first channel layer pattern 156 may overlap the first gate electrode 152a.

A second channel layer pattern 162 having a second volume larger than the first volume may be formed on the second gate insulation layer 154b. The second channel layer pattern 162 may overlap the second gate electrode 152b.

First metallic patterns 168 may be formed on the substrate 150 to contact sidewalls of the first channel layer pattern 156. The first metallic patterns 168 may be formed on the first gate insulation layer 154a, if the first gate insulation layer 154a is formed on the substrate 150. The first metallic patterns 168 may be spaced apart from the first gate electrode 152a. The first metallic patterns 168 may serve as first source/drain regions of the first transistor.

Second metallic patterns 170 may be formed on the substrate 150 to contact sidewalls of the second channel layer pattern 162. The second metallic patterns 170 may be formed on the second gate insulation layer 154b, if the second gate insulation layer 154b is formed on the substrate 150. The second metallic patterns 170 may be spaced apart from the second gate electrode 152b. The second metallic patterns 170 may serve as second source/drain regions of the second transistor. The first and second metallic patterns 168 and 170 may include substantially the same material.

The transistors having a bottom gate structure may be formed to have a desired threshold voltage by changing the volumes of the channel layer patterns 156 and 162.

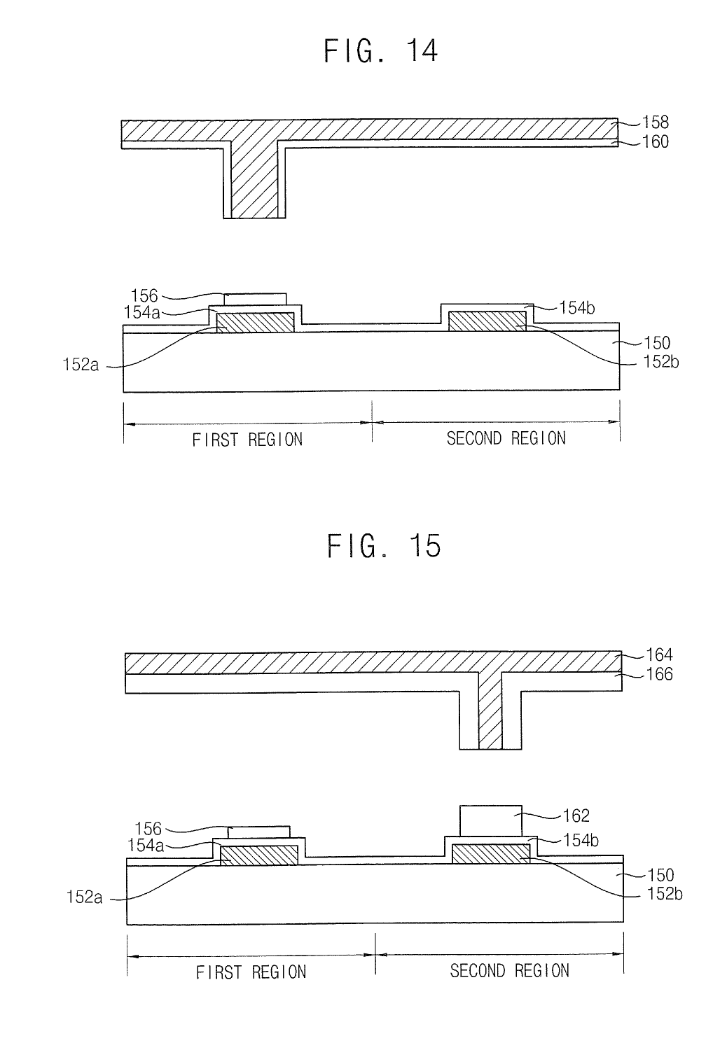

FIGS. 13 to 16 are cross-sectional views illustrating methods of manufacturing the transistors shown in FIG. 12.

Referring to FIG. 13, a substrate 150 having first and second regions may be provided. The first gate electrode 152a may be formed in the first region of the substrate 150, and the second gate electrode 152b may be formed in the second region of the substrate 150. The first and second gate electrodes 152a and 152b may be formed, for example, by a printing process or by a conventional metallization technique.

The first gate insulation layer 154a may be formed on the first gate electrode 152a, and the second gate insulation layer 154b may be formed on the second gate electrode 152b.

The first and second gate insulation layers 154a and 154b may be formed, for example, by a spin coating process. When the first and second gate insulation layers 154a and 154b are formed by a spin coating process, the first and second gate insulation layers 154a and 154b may be formed conformally, thereby having the same thickness and material composition.

Alternatively, the first and second gate insulation layers 154a and 154b may be formed by a printing process. The printing process may be performed once or more than once.

Referring to FIG. 14, the first channel layer pattern 156 may be formed on the first gate insulation layer 154a to overlap the first gate electrode 152a. The first channel layer pattern 156 may have a first volume. The first channel layer pattern 156 may be formed, for example, by a printing process.

In particular, a first channel material 160 may be coated on a first mold 158 to a first a thickness. The first mold 158 may have a protrusion corresponding to a first portion of the first gate insulation layer 154a on which the first channel layer pattern 156 may be formed. The first mold 158 may be pressed onto the substrate 150, and thus the first channel material 160 may be transferred from the protrusion of the first mold 158 to the first gate insulation layer 154a. As a result, the first channel layer pattern 156 having the first thickness and overlapping the first gate electrode 152a may be formed on the first gate insulation layer 154a.

Referring to FIG. 15, the second channel layer pattern 162 may be formed on the second gate insulation layer 154b to overlap the second gate electrode 152b. The second channel layer pattern 162 may have a second volume larger than the first volume. The second channel layer pattern 162 may be formed, for example, by a printing process.

In particular, a second channel material 166 may be coated with a second thickness larger than the first thickness on a second mold 164. The second mold 164 may have a protrusion corresponding to a second portion of the second gate insulation layer 154b on which the second channel layer pattern 162 may be formed. The second mold 164 may be pressed onto the substrate 150, and thus the second channel material 166 may be transferred from the protrusion of the second mold 164 to the second gate insulation layer 154b. As a result, the second channel layer pattern 162 having the second thickness overlapping the second gate electrode 152b may be formed on the second gate insulation layer 154b.

Referring to FIG. 16, the first metallic patterns 168 may be formed on the substrate 150 to contact the sidewalls of the first channel layer pattern 156. The first metallic patterns 168 may be formed on the first gate insulation layer 154a, if the first gate insulation layer 154a is formed on the substrate 150. Additionally, the second metallic patterns 170 may be formed on the substrate 150 to contact the sidewalls of the second channel layer pattern 162. The second metallic patterns 170 may be formed on the second gate insulation layer 154b, if the second gate insulation layer 154b is formed on the substrate 150. The first metallic patterns 168 may serve as first source/drain regions of the first transistor, and the second metallic patterns 170 may serve as second source/drain regions of the second transistor.

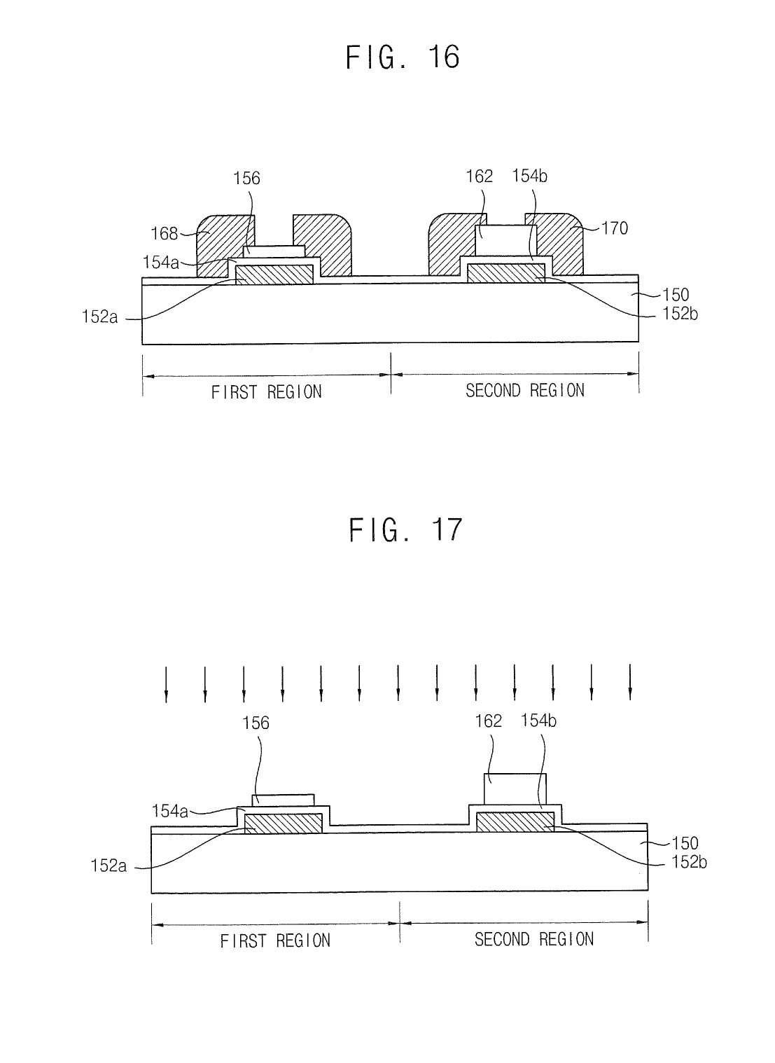

FIG. 17 is a cross-sectional view illustrating further methods of manufacturing the transistors shown in FIG. 12.

Processes substantially the same as those illustrated with reference to FIGS. 13 to 15 may be performed.

Referring to FIG. 17, ions for neutralizing hydrogen in the first and/or second channel layer patterns 156 and 162 may be implanted into the first and/or second channel layer patterns 156 and 162, so that the threshold voltage of the first and second transistors may be increased. The ions may include halogen elements, non-metallic elements having a high electronegativity, etc. such as fluorine, chlorine, bromine, indium, oxygen, sulfur, selenium, tellurium, etc. These may be doped into the first and second channel layer patterns 156 and 162 alone or in a combination thereof. The implantation may be performed by a plasma doping process, a gas vapor exposition process, a melting process, etc.

The implanted ions may be activated, e.g., by a heat treatment process.

As shown in FIG. 16, first and second metallic patterns 168 and 170 may be formed on the substrate 150 to contact the sidewalls of the first and second channel layer patterns 156 and 162, respectively.

As illustrated above, the ion implantation process may be performed onto both of the first and second channel layer patterns 154a and 154b. Alternatively, the ion implantation process may be performed onto only one of the first and second channel layer patterns 154a and 154b, which is included in a transistor having a high threshold voltage.

According to some embodiments, a semiconductor device including transistors having various threshold voltages may be easily manufactured by controlling the thickness of channel layer patterns of the transistors.

Many different embodiments have been disclosed herein, in connection with the above description and the drawings. It will be understood that it would be unduly repetitious and obfuscating to literally describe and illustrate every combination and sub-combination of these embodiments. Accordingly, all embodiments can be combined in any way and/or combination, and the present specification, including the drawings, shall be construed to constitute a complete written description of all combinations and sub-combinations of the embodiments described herein, and of the manner and process of making and using them, and shall support claims to any such combination or sub-combination.

In the drawings and specification, there have been disclosed typical embodiments of the invention and, although specific terms are employed, they are used in a generic and descriptive sense only and not for purposes of limitation, the scope of the invention being set forth in the following claims.

1. A semiconductor device, comprising:
a substrate having a first region and a second region;
a first channel layer pattern in the first region of the substrate, the first channel layer pattern having a first volume;
a second channel layer pattern in the second region of the substrate, the second channel layer pattern having a second volume;
a first transistor on the first channel layer pattern, the first transistor including a first gate insulation layer pattern on the first channel layer pattern, a first gate electrode on the first gate insulation layer and first source/drain regions in contact with the first channel layer pattern; and
a second transistor on the second channel layer pattern, the second transistor including a second gate insulation layer pattern on the second channel layer pattern, a second gate electrode on the second gate insulation layer and second source/drain regions in contact with the second channel layer pattern.

2. The semiconductor device of claim 1, wherein the first and second channel layer patterns include a semiconductor oxide.

3. The semiconductor device of claim 1, wherein the second volume is larger than the first volume, so that the first transistor has a threshold voltage higher than that of the second transistor.

4. The semiconductor device of claim 1, wherein the first transistor has a positive threshold voltage, and the second transistor has a negative threshold voltage.

5. The semiconductor device of claim 1, wherein at least one of the first and second channel layer patterns has ions implanted to neutralize hydrogen therein.

6. The semiconductor device of claim 1, wherein the first channel layer has a first thickness such that the first channel layer is fully depleted when zero bias is applied to the first gate electrode.

7. The semiconductor device of claim 6, wherein the second channel layer has a second thickness that is greater than the first thickness and that is selected such that the second channel layer is not fully depleted when zero bias is applied to the second gate electrode.

8. The semiconductor device of claim 1, wherein the substrate comprises an insulator.

9. The semiconductor device of claim 1, wherein the first channel layer and the second channel layer are formed of the same material.

10-18. (canceled)
